(19) United States
(12) Patent Application Publication
(10) Pub. No.: US 2020/0096867 A1
(43) Pub. Date: Mar. 26, 2020

(54) EDGE BEAD REMOVAL SYSTEM AND METHOD OF TREATING A SUBSTRATE

(71) Applicant: SUSS MicroTec Lithography GmbH, Garching (DE)

(72) Inventors: Ludovic LATTARD, Garching (DE); Rainer TARGUS, Garching (DE)

(21) Appl. No.: 16/582,806

(22) Filed: Sep. 25, 2019

(30) Foreign Application Priority Data
Sep. 25, 2018 (NL) 2021701

(51) Int. Cl. G03F 7/16

(52) U.S. Cl. CPC G03F 7/168

(57) ABSTRACT

An edge bead removal system for treating a substrata includes an edge bead removal head with a main body and two arms protruding from the main body. The arms are distanced from each other defining a reception space between them for accommodating a substrate to be treated. The protruding arms each have a functional surface facing each other, and wherein the functional surfaces each have at least one fluid outlet. Further, a method of treating a substrate is described.

Embodiments of the present disclosure relate to an edge bead removal system for treating a substrate. Further, embodiments of the present disclosure relate to a method of treating a substrate.

### BACKGROUND

Embodiments of the present disclosure relate in particular to the production of microstructured components by means of photolithography. Microstructures components are inter alia integrated surface, semiconductor chips or micro-electromechanical systems (MEMS). A substrate, also known as a wafer, is used for the photolithography process wherein the substrate is coated with a photoresist that is also called resist. The coated substrate is subsequently exposed by means of a mask, wherein the physical and/or chemical characteristics of the photoresist change partly due to the exposure.

Typically, the photoresist is applied on the substrate in a layer wherein it is important that the applied photoresist layer is free of irregularities or particles. Therefore, the photoresist is inter alia applied during a rotation of the substrate which process is also called spin coating. This ensures that the photoresist applied, namely the coating, is distributed as equally as possible on the surface of the substrate.

However, the spin coating results in a bead of the photoresist material at the edge of the upper side of the substrate due to the rotation of the substrate during the spin coating. In fact, the occurring centrifugal force when rotating the substrate pushes the resist material applied on the substrate radially outwards so that an edge bead is formed.

So far, the coating bead is either removed using a macro needle for solvent dispense which however is inaccurate when a wafer is bent.

It is further known that a solvent or a gas flow is used which is directed towards the substrates so as to remove the already existing edge bead or rather to remove excess material of the photoresist to prevent the bead forming on the edge. In other words, the solvent or the gas flow shall avoid the occurrence of a bead and/or remove an already existing bead d.

The known edge bead removal systems are used in the respective coater modules in which the resist material is applied on the substrate so that geometrical restrictions of the coater module have to be considered during the edge bead removal process. In general, the systems as well as the respective processes are highly sensitive to bow variation of the substrate to be treated.

### SUMMARY

Accordingly, there is a need for an edge bead removal system as well as a method of treating a substrate that allows to remove an edge bead more efficiently.

The present disclosure provides an edge bead removal system for treating a substrate, comprising an edge bead removal head with a main body and two arms protruding from the main body, wherein the arms are distanced from each other defining a reception space between them for accommodating a substrate to be treated, wherein the arms each have a functional surface facing each other, and wherein the functional surfaces each comprise at least one fluid outlet.

Accordingly, the edge bead removal system uses a separately formed edge bead removal head that is substantially C-shaped since the edge bead removal head has a main body and two arms that protrude from the main body, in particular from the same side of the main body. Thus, the main body and the two arms together form the reception space for the substrate to be treated wherein the reception space is opened to only one side for accommodating the substrate to be treated. As both arms each have the functional surface with the at least one fluid outlet, a fluid flow can be directed from the respective fluid outlets towards the reception space and the substrate accommodated in the reception space. Accordingly, a first fluid flow may be directed towards the upper surface of the substrate, in particular on the photoresist material applied on the upper surface of the substrate. Furthermore, a second fluid flow may be directed towards the lower side of the substrate that is not coated with the photoresist material.

However, the second fluid flow may be directed to an edge or along the edge of the substrate to be treated so as to generate a negative pressure or rather a vacuum on the upper side of the substrate. An already existing edge bead or rather resist material forming the edge bead is removed due to the negative pressure or rather the vacuum generated. This generally corresponds to the principle of a jet pump, in accordance with which a transporting flow is generated on the upper side of the substrate by means of the fluid flow flowing along the edge of the substrate from the lower side towards the upper side. In fact, the fluid flow generated draws the excess photoresist material so as to avoid an edge beam. In other words, a bead of the photoresist material that generally occurs on the edge of the upper side of the substrate due to the spin coating can be prevented in a simple manner by virtue of the fact that a suitable fluid flow is directed at the lower edge of the substrate, namely the second fluid flow.

According to an aspect, the at east one fluid outlet (of each functional surface) is assigned to a nozzle. Therefore, the velocity of the fluid flow can be altered due to the nozzle. Particularly, the velocity of the fluid flow is increased. Furthermore, the nozzle may ensure that the fluid flow originating from the at least one fluid outlet can be directed easily.

In fact, each functional surface may comprise a nozzle, multiple nozzles, an outflow slot, a so-called airblade, a brush-like outflow unit or similar, by way of which intra alia another profile of the fluid flow is achieved. This is in particular of important for non-round substrates, by way of example square substrates.

According to another aspect the at least one fluid outlet is connected with a nitrogen line embedded in the edge bead removal head. Therefore, a nitrogen flow or generally a gas flow may be dispensed by the at least one fluid outlet (of each functional surface). In other words, nitrogen is used for removing the edge bead or rather for preventing the existence of an edge bead wherein the respective gas flow is directed towards the substrate to be treated. The fluid flow provided by the at least one fluid outlet connected with the nitrogen line may be free from solvents. This ensures that no further substances are introduced since a chamber of the edge bead removal system may be generally flooded with nitrogen. The chamber accommodates the edge bead removal head as well as the substrate to be treated in a certain atmosphere. In fact, the nitrogen flow is used to remove the excess resist material in a substantially mechanical or rather physical manner.

In general, the nitrogen line may be connected to a nitrogen source providing the nitrogen used by the at least one fluid outlet.

According to another embodiment, the at least one fluid outlet is connected to a solvent line embedded in the edge bead removal head. Therefore, a solvent may be used for removing the already existing edge bead or rather to prevent the existence of an edge bead. The solvent flow may be directed directly on the resist material to remove the resist material directly. Thus, the excess resist material is removed in a substantially chemical manner. The solvent may be acetone or any other suitable solvent for the respective photoresist material.

In general, the solvent line may be connected to a solvent source providing the solvent used by the at least one fluid outlet.

According to an embodiment, each functional surface has at least two fluid outlets. Therefore, the at least two fluid outlets may be connected to the nitrogen line as well as the solvent line so that both fluid flows may generally be used for removing the edge bead. In fact, the user of the edge bead removal system may select the respective fluid for removing the edge bead. Moreover, a control unit of the edge bead removal system may control the respective nitrogen source or rather solvent source in an automatic manner.

Since each functional surface of the edge bead removal head may be connected with a solvent line and a nitrogen line respectively, a solvent flow and a nitrogen flow may be directed towards the substrate from its lower side as well as its upper side. Accordingly, the flexibility in terms of edge bead removal processing is maximized due to the specific design of the edge bead removal head.

An aspect provides that the at least one fluid outlet is inclined with respect to the respective functional surface. Hence, the fluid flow assigned to the at least one fluid outlet may be directed towards the reception space in an inclined manner with respect to the functional surface. Hence, the orientation of the fluid flow may be different to a perpendicular orientation. This ensures that a negative pressure or rather a vacuum may occur on the upper side of the substrate easily even though the fluid flow originates from the functional surface that faces the lower side of the substrate. In fact, the respective fluid flows along the edge so as to draw the material at the edge of the upper side of the substrate.

Moreover, the main body may comprise a drainage opening assigned to the reception space, wherein the drainage opening is connected to a vacuum source. Thus, any material or rather particles that may occur during the edge bead removal process can be sucked by the vacuum to which the drainage opening is connected. This ensures that any impurities are removed effectively from the chamber so that the coating of the substrate, namely the photoresist material applied on the substrate, is not harmed or impurified.

Moreover, the edge bead removal head may comprise an edge sensor that is configured to sense the edge of the substrate to be treated. Accordingly, it is ensured that the distance of the at least one fluid outlet with respect to the edge of the substrate is maintained stable during the treating process. For this purpose, the edge sensor may be connected with a control unit of the edge bead removal system so that the relative position of the edge bead removal head can be controlled appropriately ensuring that the distance to the edge is constant during the edge bead removal process. In fact, the edge sensor is configured to sense the relative horizontal distance between the edge of the substrate and the at least one fluid outlet.

Furthermore, a sensor may be provided that is configured to sense the vertical distance between the functional surface and a corresponding side of the substrate for instance the upper side of the substrate or rather the lower side of the substrate.

Furthermore, the edge bead removal system may comprise a linear drive that is connected with the edge bead removal head. Therefore, the edge bead removal head may be driven appropriately so as to ensure that the (relative horizontal) distance remains constant. For instance, the linear drive may ensure that the edge bead removal head can be moved in a radial manner along the edge of the round substrate. In other words, the linear drive moves the edge bead removal head along the circumference of the substrate.

In addition, the same linear drive or another linear drive is configured to control vertical movement of the edge bead removal head with respect to the substrate so that the vertical distance of the functional surface to the respective side of the substrate is set appropriately. Hence, the relative vertical distance may be maintained constant during the edge bead removal process.

According to another aspect, the edge bead removal system comprises an edge bead removal chuck with a processing surface for holding the substrate to be treated. Particularly, the processing surface has a diameter up to 280 mm, for example. In fact, the edge bead removal process may be done in external module with respect to the coater module in which the photoresist material is applied on the upper surface of the substrate. Therefore, a large edge bead removal chuck being different to a processing chuck within the coater module can be used. The respective edge bead removal chuck ensures that large substrates or rather large wafers can be flattened substantially over their entire diameter. In fact, this ensures that the edge bead removal system is less dependent on any bow of the substrate since the edge bead removal chuck has a diameter that matches the diameter of the (large) substrate. In other words, the dependency between the bow and the edge bead removal accuracy is strongly reduced.

In general, the processing surface of the edge bead removal chuck may be connected to a vacuum source. Therefore, the substrate may be positioned on the edge bead removal chuck, in particular centered, via the vacuum applied. The vacuum applied further ensured that the substrate is flattened on the processing surface appropriately.

In addition, the edge bead removal head may comprise a distance adjustment unit that is configured to adjust the distance between the arms such that the volume of the reception space is adjustable. Accordingly, at least one arm of the arms protruding from the main body may be displaced along the main body relative to the other arm so that the distance between both arms can be set in a desired manner. This ensures that substrates having different thicknesses may be processed by the same edge bead removal system, in particular the same edge bead removal head.

Another aspect provides that the edge bead removal system is configured to move the edge bead removal head in a horizontal direction in order to maintain the horizontal distance of the at least one fluid outlet with respect to the edge of the substrate constant. During the treatment of the substrate, namely the respective edge bead removal process, the edge bead removal head is moved in a horizontal direction so that the relative horizontal distance between the at least one fluid outlet and the edge of the substrate is maintained constant. For this purpose, the linear drive is controlled appropriately. In fact, the edge bead removal head is driven along the circumference of the substrate by the linear drive.

Moreover, the edge sensor senses the edge of the substrate to be treated and forwards the respective information so that the linear drive is controlled in response to the information retrieved by the edge sensor. The relative horizontal position of the at least one fluid outlet with respect to the edge is measured by the edge sensor wherein the linear drive moves the edge bead removal head so as to keep the horizontal distance constant.

In fact, the components of the edge bead removal system, namely the edge sensor, the linear drive and/or the control unit, ensure that the (horizontal) distance of the at least one fluid outlet with respect to the edge of the substrate is maintained constant during the treatment of the substrate. Accordingly, the edge bead removal system is configured to maintain the (relative) horizontal distance constant.

In general, the functional surfaces of the edge bead removal head extend in the horizontal direction.

The processing surface of the edge bead removal chuck also extends in the horizontal direction.

Further, the surface of the substrate, on which the photoresist material is applied, substantially extends in the horizontal direction.

The arms of the edge bead removal head are spaced apart from each other in a vertical direction being perpendicular to the horizontal direction.

Further, the present disclosure provides a method of treating a substrate, comprising the following steps:
Providing an edge bead removal system, in particular the edge bead removal system as described above, having an edge bead removal head that provides a reception space between two arms of the edge bead removal head.
Providing a substrate to be treated, and
Positioning the edge bead removal head and the substrate so that the substrate is accommodated in the reception space between the arms of the edge bead removal head.

This ensures that the upper side as well as the lower side of the substrate can be treated by the edge bead removal system easily. Particularly, both sides or rather surfaces of the substrate can be treated simultaneously. Furthermore, the advantages mentioned above also apply to the method of treating the substrate in a similar manner.

In general, the method of treating a substrate for removing the edge bead as well as the edge bead removal system are performed on a flattened substrate or rather a flattened wafer. This can be ensured by the specific edge bead removal chuck only used for edge bead removal by the edge bead removal system.

Particularly, the accuracy of the edge bead removal system mainly depends on the accuracy of the edge sensor and/or the accuracy of the linear drive. Hence, other effects impairing the accuracy in removal system known in the prior art do not have an effect.

In fact, the edge bead removal system is no longer dependent on the wafer type. Particularly, the reception space is big enough for accommodating different types of wafers. In case of a very large or a very small wafer, the volume of the reception space may be adjusted appropriately.

Generally, the edge bead removal system is efficient since the volume of the fluid used for edge bead removal is minimized due to the compact design of the edge bead removal system, namely the minimized distance of the fluid outlets with respect to the substrate.

### DESCRIPTION OF THE DRAWINGS

The foregoing aspects and many of the attended advantages of the claimed subject matter will become more readily appreciated as same become better understood by reference to the following detailed description, when taken in conjunction with the accompanying drawings, wherein:

FIG. 1 schematically shows a cross-sectional view of a part of an edge bead removal system according to the present disclosure; and

FIG. 2 schematically shows a flow chart illustrating a method of treating a substrate according to the present disclosure.

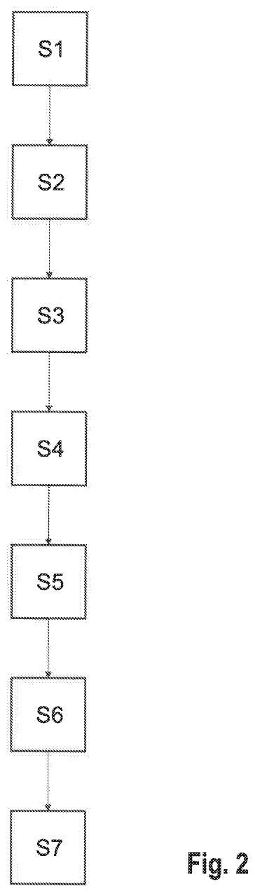

### DETAILED DESCRIPTION

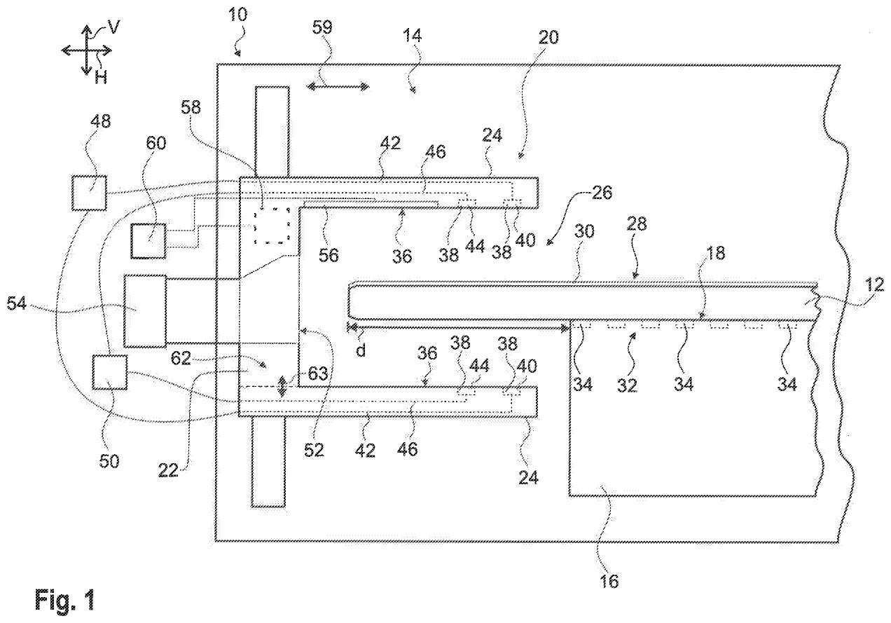

In FIG. 1, an edge bead removal system 10 for treating a substrate 12 is shown.

The edge bead removal system 10 comprises a chamber 14 in which an edge bead removal chuck 16 is positioned that has a processing surface 18 on which the substrate 12 is placed for being treated by the edge bead removal system 10.

Further, edge bead removal system 10 comprises an edge bead removal head 20 that is also located within the chamber 14. The edge bead removal head 20 has a main body 22 and two arms 24 protruding from the main body 22. The arms 24 are spaced apart from each other in a vertical direction V which is perpendicular to a horizontal direction H.

The vertical direction V as well as the horizontal direction H are illustrated in a separate diagram shown in FIG. 1.

In fact, the edge bead removal head 20 is substantially C-shaped from a side view as shown in FIG. 1 since the arms 24 are distanced from each other so as to define a reception space 26 that accommodates the substrate 12 to be treated partly.

As shown in FIG. 1, the substrate 12 has an upper side 28 that is coated with a photoresist material 30 whereas a lower side 32 of the substrate 12 is not coated with the photoresist material. The substrate 12 is placed on the edge bead removal chuck 16, in particular its processing surface 18, via its lower side 32.

The edge bead removal chuck 16 is connected with a vacuum source that generates a negative pressure so as to suck the substrate 12 onto its processing surface 18 which ensures that the substrate 12 is flattened appropriately. Several vacuum outlets 34 are assigned to the processing surface 18 via which the substrate 12, in particular its lower side 32, is sucked by the vacuum.

Furthermore, the edge bead removal chuck 16 is different with respect to typical processing chucks used in coater modules since the edge bead removal chuck 16, in particular its processing surface 18, has a diameter up to 280 mm. Hence, the substrate 12 may have a diameter up to 300 mm so that the substrate 12 overlaps the edge bead removal chuck 16 radially by a distance d being 10 mm as indicated in FIG. 1.

Typically, the substrate 12 is coated with the photoresist material 30 on its upper side 28, also called upper surface, so that an edge bead may occur due to the spin coating used for applying the photoresist material onto the upper side 28 of the substrate 12. This edge bead typically occurs within the outer 10 mm of the substrate 12 that is accommodated in the reception space 26 of the edge bead removal head 20.

As shown in FIG. 1, both arms 24 each have a functional surface 36 facing each other as well as the substrate 12 accommodated in the reception space 26.

In fact, the first arm 24 has a functional surface 36 that faces the upper side 28 of the substrate 12 whereas the second arm 24 has a functional surface 36 that faces the lower side 32 of the substrate 12.

In the shown embodiment, both functional surfaces 36 each have two fluid outlets 38, also called fluid openings. The first fluid outlet 40 of each functional surface 36 is assigned to a nitrogen line 42 that is embedded in the edge bead removal head 20 whereas the second fluid outlet 44 is assigned to a solvent line 46 that is also embedded in the edge bead removal head 20.

The nitrogen line 42 is guided out of the chamber 14 for being connected with a nitrogen source 48. In a similar manner, the solvent line 46 is guided out of the chamber 14 for being connected with a solvent source 50.

In general, the fluid outlets 38 may be inclined with respect to the respective functional surface 36 so that the fluid flow originating from the respective fluid outlet 36 is inclined with respect to the functional surface 36 so that the fluid flow is directed towards the reception space 26 or rather the substrate 12 in an inclined manner.

This ensures that the respective fluid flow does not impair the characteristics of the substrate 12, in particular the photoresist material 30 applied previously.

In fact, the fluid flow originating from the fluid outlet 38 facing the upper side 28 of the substrate 12 may only scrub along the photoresist material 30 applied on the substrate 12.

In contrast thereto, the fluid flow originating from the fluid outlet 38 facing the lower side 32 of the substrate 12 may be directed so as to generate a negative pressure or rather a vacuum on the upper side 28 of the substrate 12 so as to remove the excess photoresist material 30 of an already existing edge bead or rather the excess photoresist material 30 that may form the edge bead.

In general, the fluid flows originating from the fluid outlets 38 may deliver or rather release particles that may disturb or rather impair the characteristics of the substrate 12, in particular the photoresist material 30 applied thereon. For instance, the solvent flow provided by the fluid outlets 38 connected with the solvent line 46 discharges solvent into the chamber 14.

Accordingly, the edge bead removal head 20, in particular its main body 22, has a drainage opening 52 that is assigned to the reception space 26 wherein the drainage opening 52 is connected to a vacuum source 54.

Thus, impurities or rather particles that may occur during the edge bead removal process are sucked away from the reception space 26 via the drainage opening 52 that is allocated to the edge of the substrate 12 as shown in FIG. 1.

This ensures that the photoresist material 30 applied on the substrate 12 is not impurifled or impaired by particles or solvent. As already mentioned, the nitrogen discharged by the fluid outlets 38 connected with the nitrogen line 42 does not impair the photoresist material 30 since the chamber 14 may be flooded by nitrogen.

Generally, the respective fluid outlets 38, namely the ones assigned to the nitrogen line 42 or rather the solvent line 46, may comprise at least one nozzle, a channel-like shape, an outflow slot, a brush-like shape, a so-called airblade (discharging solvent or rather nitrogen) or similar. In fact, the speed of the fluid flow as well as its shape may be altered by the respective design of the fluid outlets 38.

Furthermore, the edge bead removal head 20 comprises an edge sensor 56 that is configured to sense the edge of the substrate 12 to be treated. In fact, the horizontal position of the edge of the substrate 12 (with respect to the edge bead removal head 20 or a component thereof) is sensed by the edge sensor 56.

In addition, the edge bead removal system 10 comprises a iinear drive 58 that is connected with the edge bead removal head 20 so that the edge bead removal head 20 can be driven by the linear drive 58 in order to keep the distance to the substrate 12 in the desired manner.

The linear drive 58 ensures that the fluid outlets 38 of the edge bead removal head 20 have the same (relative horizontal) distance to the edge of the substrate 12.

For this purpose, the edge bead removal head 20 is driven along the circumference of the substrate 12 appropriately.

The respective movement of the edge bead removal head 20 is indicated by arrow 59 illustrating the horizontal movement direction. Thus, the horizontal movement direction, namely arrow 59, is parallel to the horizontal direction H.

In fact, the edge sensor 56 and the linear drive 58 ensure that the (horizontal) distance of the fluid outlets 38 with respect to the edge of the substrate 12 is maintained constant.

The relative horizontal position of the fluid outlets 38 with respect to the edge is measured by the edge sensor 56 wherein the linear drive 58 moves the edge bead removal head 20 so as to keep the horizontal distance constant.

For this purpose, the edge sensor 56 as well as the linear drive 58 are connected with a control unit 60 that receives the respective data from the edge sensor 56 and controls the linear drive 58 appropriately.

Hence, the edge bead removal system 10 is configured to move the edge bead removal head 20 in a horizontal direction so that the horizontal distance of the fluid outlets 38 with respect to the edge of the substrate 12 is maintained constant.

In addition, the relative vertical position can also be controlled appropriately. Thus, the same linear drive 58 or another linear drive may drive the edge bead removal head 20 so as to keep the vertical distance between the functional surface 36 and the substrate 12 constant, in particular a corresponding surface of the substrate 12.

The control unit 60 may also control the edge bead removal chuck 16, in particular its rotating speed, during the edge bead removal process. In general, the rotating speed may be low due to the minimal distance between the fluid outlets 38 and the substrate 12. Accordingly, the edge bead removal chuck 16 can be provided in a cost-efficient manner since a low cost engine may be used for the edge bead removal chuck 16 since the rotating speeds required are low. The low rotating speed further improves the cleaning efficiency.

Further, the control unit 60 may also control the nitrogen line 42 or rather the nitrogen source 48 as well as the solvent line 46 or rather the solvent source 50.

In a similar manner, the control unit 60 is configured to control the vacuum that is provided at the edge bead removal chuck 16 for positioning and flattening the substrate 12 placed on the processing surface 18 of the edge bead removal chuck 16.

The control unit 60 may further control the vacuum source 54 assigned to the drainage opening 52 for sucking impurities or rather particles that may occur during the edge bead removal process.

In general, the arms 24 may be distanced with respect to each other such that the reception space 26 provided is large enough for accommodating several different types of substrates 12.

However, a distance adjustment unit 62 may be provided that ensures that the (vertical) distance between both arms 24 can be adjusted so as to adapt the volume of the reception space 26 with respect to the substrate 12 to be treated.

In other words, the distance adjustment unit 62 is configured to adjust the vertical distance between both arms 24 by adjusting the vertical distance of at least one arm 24 with respect to the other arm 24. In FIG. 1, this is schematically shown for the lower arm 24 that can be moved along arrow 63 in the vertical direction V with respect to the other arm 24.

Accordingly, the volume may be reduced or rather increased depending on the size of the substrate 12, in particular its thickness. In the shown embodiment, the substrate 12 has a typical thickness of 775 μm. However, this thickness may differ depending on the type of substrate.

Moreover, the chamber 14 that accommodates at least the edge bead removal chuck 16 as well as the edge bead removal head 10 may be different to the coating chamber of the coating module in which the substrate 12 is coated with the photoresist material 30.

In general, the edge bead removal system 10 is very compact due to the compact design of the edge bead removal head 20 accommodating the substrate 12, in particular the edge of the substrate 12.

The substrate 12 is generally treated by providing the edge bead removal system 10 (Step S1).

Further, the substrate 12 to be treated is also provided (Step S2),

Then, the substrate 12 as well as the edge bead removal head 20 are positioned such that the substrate 12 is accommodated via its edge in the reception space 26 provided by the edge bead removal head 20 (Step S3).

The edge sensor 56 senses the edge of the substrate 12 to provide data for aligning the edge bead removal head 20 appropriately (Step S4).

For this purpose, the control unit 60 controls the linear drive 58 such that the edge bead removal head 20 is aligned with the substrate 12 in the intended manner (Step S5).

Once, the edge bead removal head 20 and the substrate 12 are aligned with respect to each other, the control unit 60 may control the edge bead removal chuck 16 to rotate (Step S6).

Furthermore, the control unit 60 may control the nitrogen source 48 and/or the solvent source 50 to provide nitrogen or rather solvent for treating the substrate 12 appropriately so as to remove excess photoresist material 30 (Step S7). Hence, an upcoming edge bead can be prevented or rather an already edge bead is removed,

In fact, the edge bead removal system 10 as well as the method of treating the substrate 12 ensure that the edge bead removal processes are independent from any bows of the substrate 12 since a separately formed edge bead removal chuck 16 having a diameter adapted to the substrate 12 can be used. This separately formed edge bead removal chuck 16 is used in a different module with regard to the coating module, namely an edge bead removal module or rather the edge bead removal system 10.

1. An edge bead removal system for treating a substrate, comprising an edge bead removal head with a main body and two arms protruding from the main body, wherein the arras are distanced from each other defining a reception space between them for accommodating a substrate to be treated, wherein the arms each have a functional surface facing each other, and wherein the functional surfaces each comprise at least one fluid outlet.

2. The edge bead removal system according to claim 1, wherein the at least one fluid outlet is assigned to a nozzle.

3. The edge bead removal system according to claim 1, wherein the at least one fluid outlet is connected with a nitrogen line embedded in the edge bead removal head.

4. The edge bead removal system according to claim 1, wherein the at least one fluid outlet is connected to a solvent line embedded in the edge bead removal head.

5. The edge bead removal system according to claim 1, wherein each functional surface has at least two fluid outlets.

6. The edge bead removal system according to claim 1, wherein the at least one fluid outlet is inclined with respect to the respective functional surface.

7. The edge bead removal system according to claim 1, wherein the main body comprises a drainage opening assigned to the reception space, wherein the drainage opening is connected to a vacuum source.

8. The edge bead removal system according to claim 1, wherein the edge bead removal head comprises an edge sensor that is configured to sense the edge of the substrate to be treated.

9. The edge bead removal system according to claim 1, wherein the edge bead removal system comprises a linear drive that is connected with the edge bead removal head.

10. The edge bead removal system according to claim 1, wherein the edge bead removal system comprises an edge bead removal chuck with a processing surface for holding the substrate to be treated.

11. The edge bead removal system according to claim 10, wherein the processing surface has a diameter up to 280 mm.

12. The edge bead removal system according to claim 1, wherein the edge bead removal head comprises a distance adjustment unit that is configured to adjust the distance between the arms such that the volume of the reception space is adjustable.

13. The edge bead removal system according to claim 1, wherein the edge bead removal system is configured to move the edge bead removal head in a horizontal direction in order to maintain the horizontal distance of the at least one fluid outlet with respect to the edge of the substrate constant.

14. A method of treating a substrate, comprising the following steps:
Providing an edge bead removal system having an edge bead removal head that provides a reception space between two arms of the edge bead removal head,
Providing a substrate to be treated, and
Positioning the edge bead removal head and the substrate so that the substrate is accommodated in the reception space between the arms of the edge bead removal head.
